(19) United States
(12) Patent Application Publication
(10) Pub. No.: US 2008/0169944 A1
(43) Pub. Date: Jul. 17, 2008

(54) Dynamic Number Keypad for Networked Phones

(75) Inventors: ARTHUR G. HOWARTH, ORLEANS (CA); JOHN A. TOEBES, CARY, NC (US)

Correspondence Address: CISCO SYSTEMS, INC.;SCIENTIFIC-ATLANTA, INC., SA/CISCO IP DEPT., 5030 SUGARLOAF PARKWAY, LAWRENCEVILLE, GA, 30044, US

(73) Assignee: CISCO TECHNOLOGY, INC., SAN JOSE, CA (US)

(21) Appl. No.: 11/623,284

(22) Filed: Jan. 15, 2007

(51) Int. Cl. H03M 11/00

(52) U.S. Cl. 341/23

(57) ABSTRACT

Methods and apparatus for allowing images displayed on a keypad of a networked phone to be dynamically changed are disclosed. According to one aspect of the present invention, a networked phone apparatus includes a dynamic keypad and control channel logic. The dynamic keypad has a plurality of dynamic keys that each display images. The control channel logic causes the images displayed on the plurality of dynamic keys to be changed. The networked phone apparatus may be a hardware based phone apparatus or a software based phone apparatus.

### BACKGROUND OF THE INVENTION

The present invention relates generally to interactive voice response (IVR) systems associated with call centers.

An IVR system is often used in a call center system to qualify and to filter the requirements of a caller prior to involving a human at the call center end. For example, a user may be asked to provide information relating to the purpose of his or her call such that his or her call may be routed to an appropriate call center representative. The information may be provided orally and, in some cases, either orally or by entering numbers into a keypad of a phone.

While IVR systems are effective, callers into or users of IVR systems generally navigate through many levels of menus and many questions before achieving an intended goal, e.g., the completion of a transaction or a connection to a call center representative. Navigating through multiple menus and answering multiple questions may be complicated, as there may be uncertainty as to what an appropriate response may be. For instance, a user may be unsure as to which number to enter into a keypad of a phone to activate a particular option.

### BRIEF DESCRIPTION OF THE DRAWINGS

The invention may best be understood by reference to the following description taken in conjunction with the accompanying drawings in which:

FIG. 1A is a diagrammatic representation of a dynamic keypad of a phone in accordance with an embodiment of the present invention.

FIG. 1B is a diagrammatic representation of a dynamic keypad, e.g., dynamic keypad 108 of FIG. 1A, on which numeric phone keys are displayed in accordance with an embodiment of the present invention.

FIG. 2 is a diagrammatic representation of a dynamic keypad on which keys which are associated with a voice mailbox application are displayed in accordance with an embodiment of the present invention.

FIG. 3 is a diagrammatic representation of a dynamic keypad on which keys associated with a pay-per-view application are displayed in accordance with an embodiment of the present invention.

FIG. 4 is a diagrammatic representation of a dynamic keypad on which keys with numbers and icons that are suitable for use by young children are displayed in accordance with an embodiment of the present invention.

FIG. 5A is a block diagram representation of a first overall system that allows dynamic keys to be displayed in accordance with an embodiment of the present invention.

FIG. 5B is a block diagram representation of a second overall system that allows dynamic keys to be displayed in accordance with an embodiment of the present invention.

FIG. 6A is a process flow diagram which illustrates a method of soliciting and obtaining input via a dynamic keypad in which an interactive voice response system substantially automatically displays menu-specific keys in accordance with an embodiment of the present invention.

FIG. 6B is a process flow diagram which illustrates a method of soliciting and obtaining input via a dynamic keypad in which an interactive voice response system displays menu-specific keys in response to a request in accordance with an embodiment of the present invention.

FIG. 7A is a process flow diagram which illustrates a method of utilizing dynamic keys that are substantially automatically provided in accordance with an embodiment of the present invention.

FIG. 7B is a process flow diagram which illustrates a method of requesting and utilizing dynamic keys in accordance with an embodiment of the present invention.

### DESCRIPTION OF THE EXAMPLE EMBODIMENTS

### General Overview

In one embodiment, a networked phone apparatus includes a dynamic keypad and control channel logic. The dynamic keypad has a plurality of dynamic keys that each display images. The control channel logic causes the images displayed on the plurality of dynamic keys to be changed.

### Description

Networked phones, which may be software and/or hardware based, are often used in voice over Internet Protocol (VoIP), or similar, networks to access interactive voice response (IVR) systems of call centers. To reduce the response times associated with IVR systems, a networked phone may be provided with a dynamic or organic keypad. A dynamic keypad includes dynamic or core keys on which images, icons, and/or graphics may be displayed. Displaying key functions on the keys of a dynamic keypad provides a user with the capability to quickly respond to audible options associated with an IVR system, as dynamic keys may be arranged to display images associated with menu options of an IVR application. For example, in a voice mail application, dynamic keys may include a key on which an image which identifies a “play” key or button is displayed. Hence, if a user receives an audible command from the voice mail application to select an option, the user may view his or her dynamic keyboard, and readily identify the key on which a “play” image is displayed as the key to select in order to play a message. The ability to visually view options may enable a selection of an option to be made more efficiently than if a user has to either listen to audible explanations of options before making a selection, or if the user has to remember which key is likely to be associated with his desired option.

In general, the displays on dynamic keys are effectively configured to be consistent with the audible options available on IVR applications. That is, the flow associated with the IVR application is maintained such that the same numeric keys are pressed or otherwise selected by a user regardless of whether a phone includes a dynamic keypad or a standard keypad. Dynamic keys are displayed, for example, such that if a user would select ‘1’ on a standard keypad to play voicemail, the ‘1’ key on a keypad would be arranged to display a “play” image such that the input provided to an IVR application by the user is effectively the same regardless of which type of keyboard the user is using.

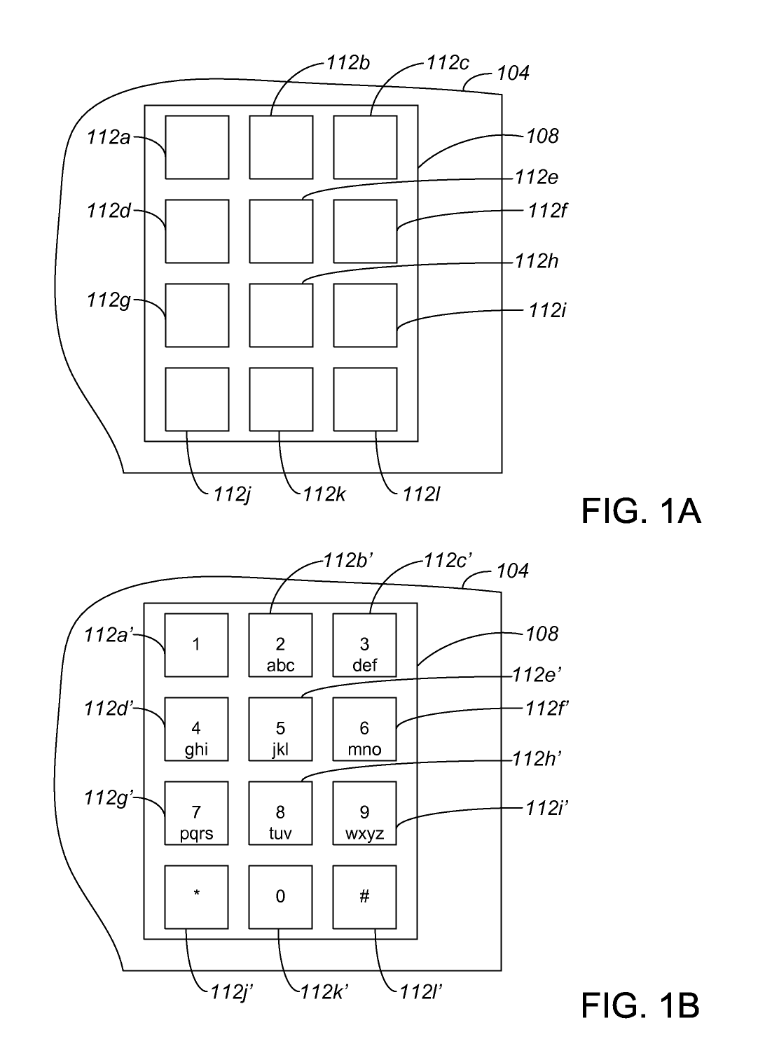

With reference to FIG. 1A, a dynamic keypad of a networked phone will be described in accordance with an embodiment of the present invention. A networked phone 104, e.g., a hardware-based or a software-based phone which uses VoIP, includes a dynamic keypad 108. Keypad 108 is, in the described embodiment, a keypad with the layout of a number keypad. Hence, keypad 108 includes approximately twelve keys 112a-l. It should be appreciated, however, that the number of keys 112a-l, as well as the orientation of keys 112a-l, in keypad 108 may vary widely. Although keys 112a-l may be actual keys or buttons, it should be appreciated that keys 112a-l may instead be images of keys displayed on a touchscreen display of networked phone 104. In one embodiment, when networked phone 104 is a software-based phone, images of keys are displayed on a display screen of a computing system which executes software or logic associated with networked phone 104.

Keys 112a-l are arranged to have images displayed thereon. If keys 112a-l are actual or hard keys, then keys 112a-l may be transparent such that light emitters (not shown) positioned under or within keys 112a-l may be seen. In other words, light emitters (not shown) are used to create images to display on keys 112a-l. The light emitters (not shown) may be organic light emitting diodes (LEDs), liquid crystal displays (LCDs), electronic ink technology, or other similar display technologies. Organic LEDs are LEDs in which the emissive layers are formed from organic compounds. Typically, organic LEDs utilize organic luminophores. In one embodiment, keys 112a-l may each effectively be organic LED displays. Electronic ink technology, as will be appreciated by those skilled in the art, typically involves using a sheet of transparent microcapsules that contain an oily solution including dye, or electronic ink, in a negatively charged titanium dioxide suspension. The microcapsules are held in a liquid polymer that is sandwiched between arrays of electrodes to form a sheet that may be laminated. One suitable electronic ink technology is available from E Ink Corporation of Cambridge, Mass.

Dynamic keypad 108 may be used as a number keypad. FIG. 1B shows dynamic keypad 108 with keys 112a′-l′ that display typical images, e.g., numbers and symbols, associated with one standard number keypad. Numbers ‘1’ through ‘9’ are displayed on keys 112a′-i′, respectively, while number ‘0’ is displayed on key 112k′. Keys such as an asterisk key 112j and a pound key 112l are also displayed.

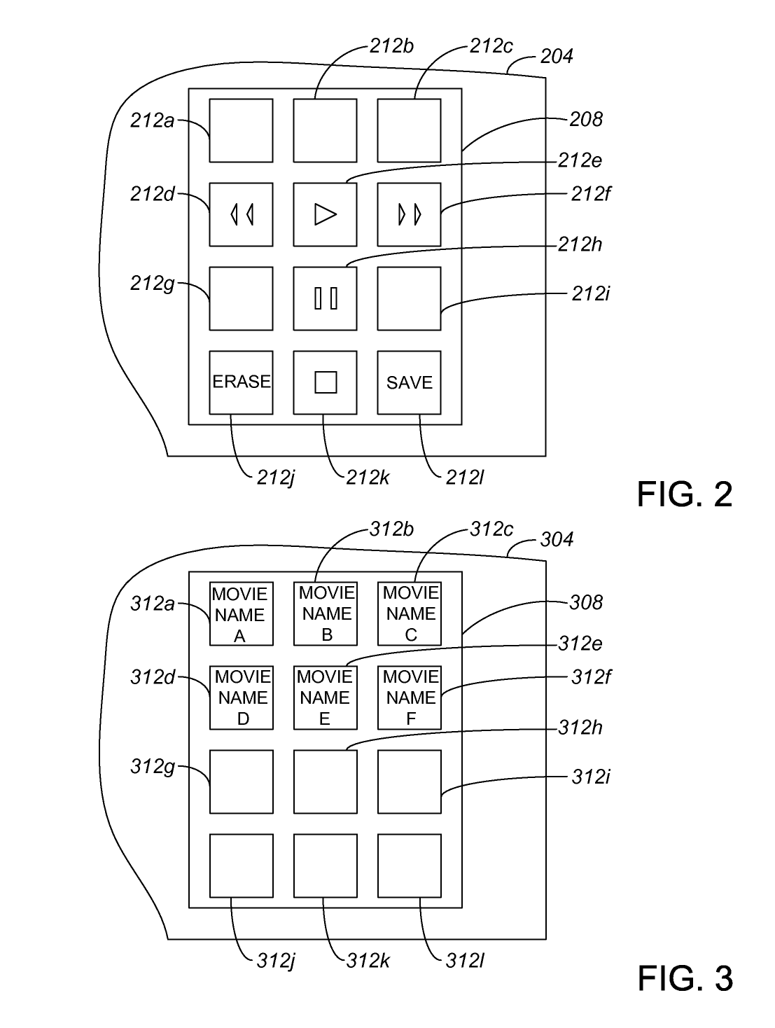

In lieu of displaying images associated with a typical number keypad, images that are specific to a particular menu of an IVR application may be displayed on keys of a dynamic keyboard. Images or icons displayed on keys may be dynamically changed to accommodate options which are available for each particular menu of an IVR application. By way of example, for an IVR application associated with voice mail, keys of a dynamic keyboard may effectively display commands that allow a user to process his or her voice mail. FIG. 2 is a diagrammatic representation of a dynamic keypad on which keys which are associated with a voice mail application are displayed in accordance with an embodiment of the present invention. A dynamic keypad 208 of a networked phone 204 includes keys 212a-l. Key 212e is arranged to display a “play” icon such that when key 212e is selected, e.g., pressed or touched, by a user, messages in the voice mailbox accessed by the user are played back. Key 212h is arranged to display a “pause” icon that allows a user to pause a message that he or she is playing back. Key 212k is arranged to display a “stop” icon that allows a user to stop a message playback process.

Keys 212d, 212f display “rewind” and “forward” images, respectively. Selecting key 212d allows a user to rewind a message, while selecting key 212f allows the user to forward through a message. Keys 212d, 212f may also be used to effectively allow a user to scroll through a queue of messages. Key 212j may display an “erase” image to indicate that if key 212j is selected, a current message that a user has access to will be erased. Conversely, key 212l may display a “save” image to indicate that if key 212l is selected, a current message that the user has access to will be saved. For instance, upon playing a message, the voice mail application may query the user to either erase or save the message. The user may select key 212j to erase the message, or the user may select key 212l to save the message. As key 212j clearly displays an “erase” image and key 212l clearly displays a “save” image, the user may be relatively certain which key to select if he or she wishes to erase the message and which key to select if he or she wishes to save the image.

It should be appreciated that some keys 212a-l may be active at any given time, and some keys 212a-l may be inactive at any given time. Keys which are not active, e.g., key 212a, may be arranged such that if a user selects such a key, a message which indicates that the key is not active may be played. However, messages which identify inactive keys and voice prompts may not necessarily be played.

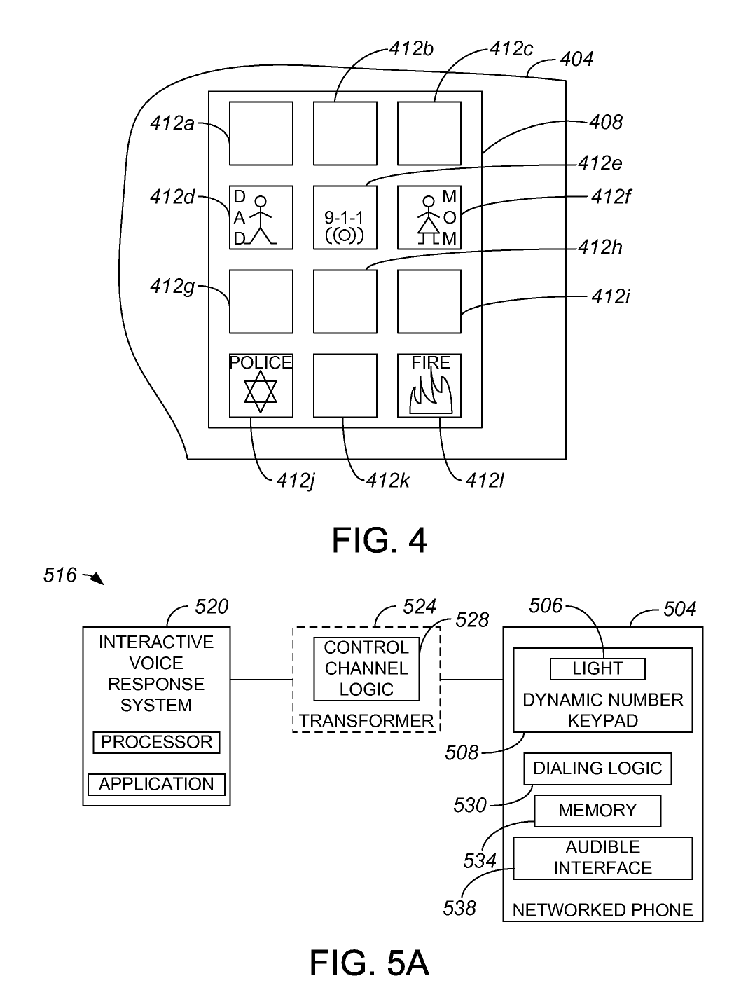

Some networked phones may be linked to systems which allow services to be ordered. For example, a networked phone may be linked to a system which allows a user to order movies to be played on his or her television. That is, a networked phone with a dynamic keypad may be in communication with an IVR application that is used to order pay-per-view movies. FIG. 3 is a diagrammatic representation of a dynamic keypad on which keys associated with a pay-per-view application are displayed in accordance with an embodiment of the present invention. A networked phone 304 includes a dynamic keypad 308 with keys 312a-l. As shown, keys 312a-f are arranged to display names of movies which may be ordered. By selecting one of keys 312a-f, a user may effectively order the movie displayed on the selected key 312a-f.

When a networked phone is not being used with an IVR application, the dynamic keypad of the networked phone may display default keys. In one embodiment, a user may be permitted to select images to be displayed on dynamic keys when keys associated with an IVR application are not displayed. Such images may be arranged to be displayed at substantially all times when an IVR application is not controlling or otherwise affecting the images displayed on dynamic keys. In other words, such images may be displayed when a networked phone does not have an active connection to any IVR application. Allowing such images to be displayed may allow the networked phone to utilize the images for speed dial or other local functions. Alternatively, such images may be arranged to be displayed substantially only when the networked phone is in use, e.g., when a user picks up the handset of a networked phone or when an incoming phone call is received, but not in use with an IVR application that has the capability to control the images.

While an IVR system may issue commands to a networked phone to modify the display of the keys, it should be understood that the functions associated with keys may be selected for an application by a user. By way of example, when utilizing the XML services or functions on an IP phones which has a display, pressing a “directories” button may initiate a display of a menu in which selecting number ‘1’ displays missed calls, selecting number ‘2’ displays received calls, selecting number ‘3’ displays placed calls, selecting number ‘4’ displays a personal directory, and selecting number ‘5’ displays a corporate directory. Dynamic keypads allow labels to be placed on the number keys to indicate the functions associated with the various keys.

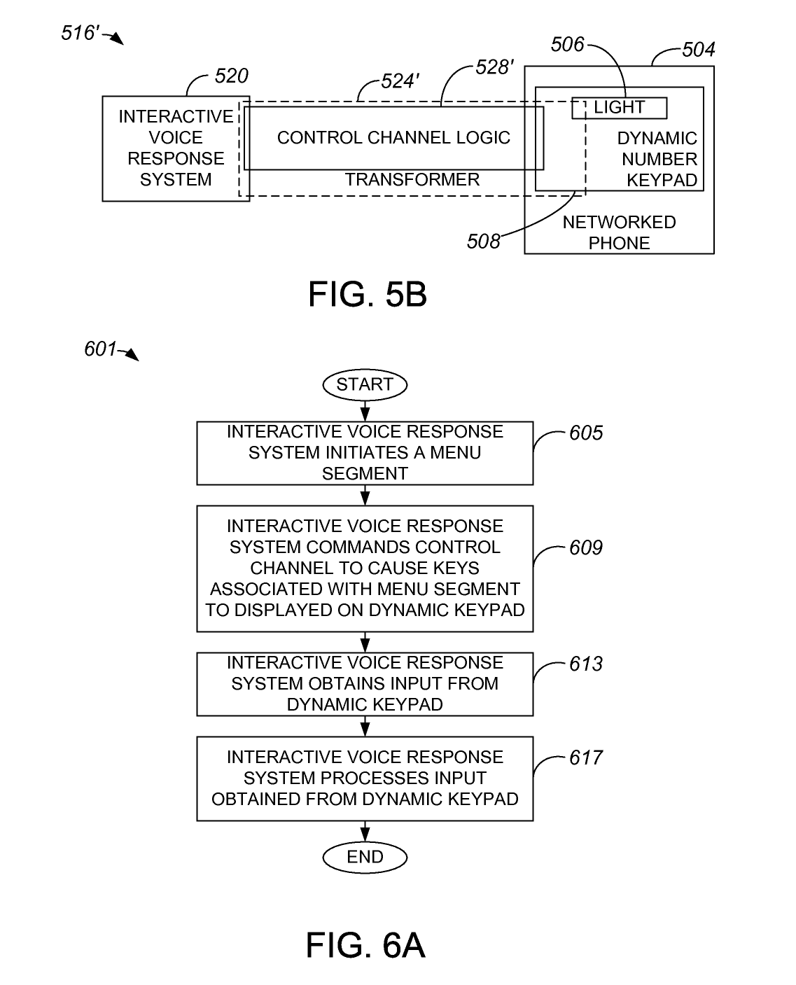

Dynamic keys of a networked phone may be used to display images which correspond to phone numbers that may be automatically dialed when the dynamic keys are selected. By selecting a key on which a particular image is displayed, a phone number associated with the image may be automatically dialed. A user may customize default keys to display images associated that the phone numbers he or she is most likely to call. FIG. 4 is a diagrammatic representation of a dynamic keypad on which keys with numbers and icons that are suitable for use by young children are displayed in accordance with an embodiment of the present invention. Dynamic keys 412a-l on a dynamic keypad 408 of a networked phone 404 display images associated with phone numbers. Keys 412e, 412j, 412l display images associated with phone numbers that a user is likely to call in the event of an emergency. Key 412d displays an image of a man which indicates that if key 412 is selected, the father of the user will be called. Similarly, key 412f displays an image of a woman which indicates that if key 412f is selected, the mother of the user will be called. Such an image may replace pieces of paper that are generally used to indicate which buttons on a phone correspond to speed dial buttons.

It should be appreciated that the default images displayed on dynamic keys of a networked phone may be overridden, e.g., by selecting a sequence of keys. For example, if a user does not wish to use keys such as keys 412a-l of FIG. 4 but instead wishes to use keys such as keys 112a′-l′ of FIG. 1B, the user may enter a predetermined sequence of keys to change the images displayed on the keys. In one embodiment, entering a predetermined sequence of keys may provide the user with a menu which allows the user to select a desired configuration for the keys.

In general, control channel logic provides an interface between an IVR system and the dynamic keypad of a networked phone. The interface allows the dynamic keypad to be configured with images that are associated with a menu of an IVR application. That is, control channel logic enables menu-specific keys associated with an IVR application to be implemented on a dynamic keypad. Such control channel logic may be implemented as a substantially separate component in an overall system that allows dynamic keys to be displayed, or may be implemented in a distributed manner within the overall system that allows dynamic keys to be displayed.

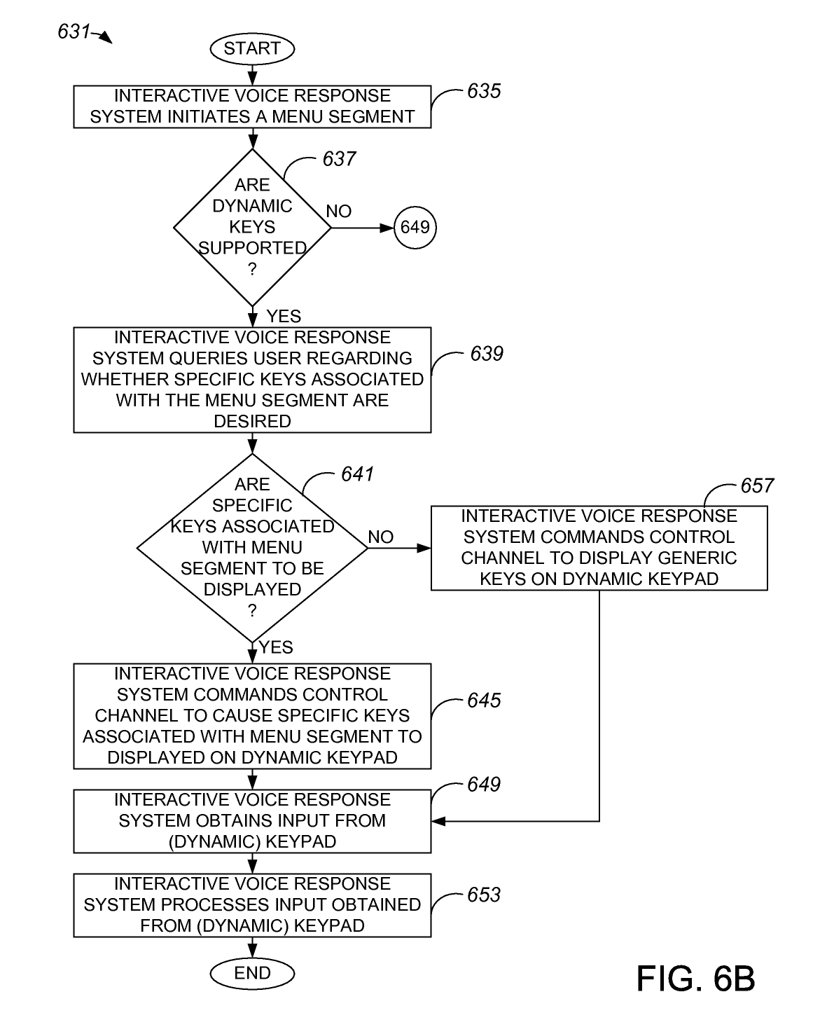

FIG. 5A is a block diagram representation of a first overall system that allows dynamic keys to be displayed in accordance with an embodiment of the present invention. An overall system 516, includes an IVR system 520 and a networked phone 504. IVR system 520 is arranged to support applications that may be accessed using networked phone 504 through a network, e.g., a VoIP network. Networked phone 504 includes a dynamic keypad 508 with light emitters 506 such as organic LEDs that allow images to be displayed on keys (not shown) of dynamic keypad 508. Dialing logic 530 of networked phone 504 is arranged to enable input received through dynamic keypad 508 to be translated into a phone number and dialed, if appropriate. In other words, dialing logic 530 is arranged to enable networked phone 504 to be used to initiate phone calls. Dialing logic 530 may be implemented as hardware devices and/or software code devices.

Networked phone 504 typically includes an audible interface 538, and may also include a memory 534. It should be appreciated that if networked phone 504 is a software based phone such as a softphone, memory 534 may generally be associated with a computing system that supports the software based phone. Audible interface 538 may include a microphone that receives the voice of a user and an output interface that allows the user to hear audible data streams transmitted to networked phone 504, e.g., from IVR system 520. Memory 534 may store default configurations associated with networked phone 504. By way of example, memory 534 may store information relating to default images displayed on keys of dynamic keypad 508 when networked phone 504 does not have an active connection to IVR system 520.

A transformer 524 which includes control channel logic 528 is in communication with both IVR system 520 and networked phone 504. Transformer 524 is arranged to transform answers to queries made by IVR system 520 into data that may be used by IVR system 520, or other systems that IVR system 520 allows to provide services. Control channel logic 528, which may be hardware logic and/or software logic embodied on an executable medium, is arranged to take information pertaining to menus of an application from IVR system 520 and use that information cause dynamic number keypad 508 to display images on dynamic keys (not shown) that are consistent with the menus. In one embodiment, control channel logic 538 causes light emitters 506 to create desired images for the dynamic keys (not shown).

Transformer 524 may be distributed on both IVR system 520 and on networked phone 504. FIG. 5B is a block diagram representation of an overall system 516′ that includes a distributed transformer 524′ in accordance with an embodiment of the present invention. Transformer 524′ and control channel logic 528′ are distributed such that control channel logic 528′ resides partially on IVR system 520 and partially on networked phone 504. In one embodiment, control channel logic 528′ provides logic on networked phone 504 that allows default images to be displayed on keys (not shown) when there is no active connection between networked phone 504 and IVR system 520.

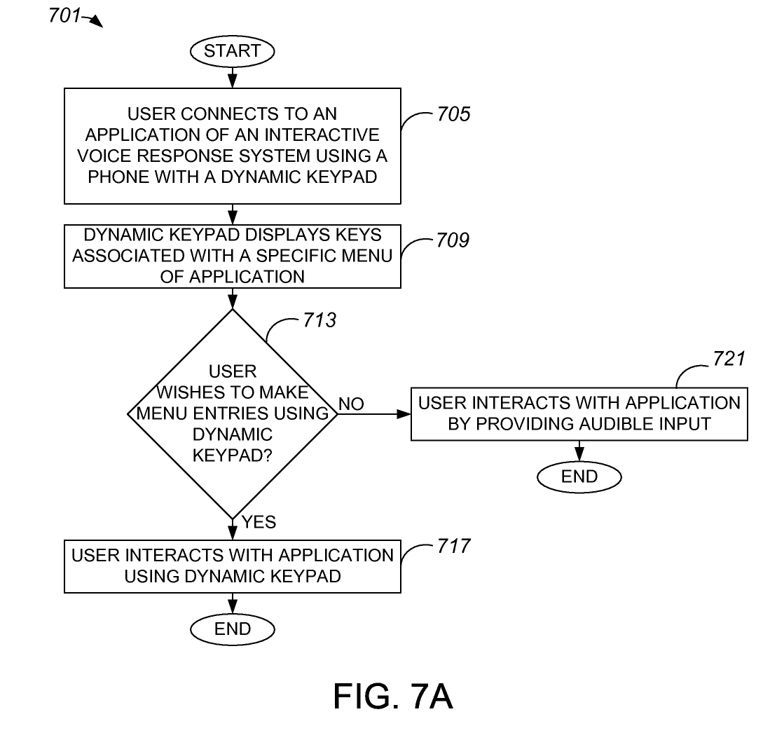

FIG. 6A is a process flow diagram which illustrates a method of soliciting and obtaining input via a dynamic keypad of a networked phone in which an interactive voice response system substantially automatically displays menu-specific keys in accordance with an embodiment of the present invention. A process 601 of soliciting and obtaining input begins at step 605 in which an IVR system initiates a menu segment. The menu segment may be substantially any menu that is associated with an application which is implemented using the IVR system. In general, the menu segment is initiated after a connection is effectively established between a networked phone of a caller or user and the IVR system.

Once the menu segment is implemented, the IVR system commands a control channel in step 609. The control channel is commanded to cause keys associated with the menu segment to be displayed as keys of a dynamic keypad, e.g., a dynamic number keypad. By way of example, for a voice mail application, the IVR system may command the control channel to display keys including a “play” key, a “fast forward” key, and a “rewind” key. Commanding the control channel may include causing the control channel to provide signals that cause light emitters in the keys of the dynamic keypad to be lit to form desired icons or images.

After specific keys associated with the menu segment are displayed on the dynamic keypad, the IVR system obtains input from the dynamic keypad in step 613. The input is provided when a user selects a key or keys of the dynamic keypad. Upon obtaining the input from the dynamic keypad, the IVR system processes the input in step 617. Processing the input may include, but is not limited to, identifying a subsequent menu segment to initiate or initiating a process based on the input. The process of soliciting and gathering input is completed once the IVR system processes the input.

In lieu of substantially automatically displaying specific keys associated with a menu segment, an IVR system may provide a user of a networked phone with a choice of whether he or she wishes to utilize menu specific keys or default keys. With reference to FIG. 6B, a method of soliciting and obtaining input using a dynamic keypad in which an IVR system allows a user to determine whether menu-specific keys are to be displayed will be described in accordance with an embodiment of the present invention. A process 631 of soliciting and obtaining input begins at step 635 in which an IVR system initiates a menu segment associated with an application that is associated with the IVR system. After the menu segment is obtained, it is determined in step 637 if dynamic keys are supported. A determination of whether dynamic keys are supported may be based on whether the networked phone supports dynamic keys, or if the application associated with the menu segment supports dynamic keys.

If it is determined that dynamic keys are supported, the IVR system queries a user of a networked phone in step 639 to allow the user to specify whether keys specific to the menu segment are to be displayed on a dynamic keyboard of the networked phone. The query may be audible, and the user may respond to the query verbally or by entering an appropriate key sequence into the dynamic keypad. In one embodiment, keys on the dynamic keypad may be dynamically configured to allow a user to select a “display menu-specific keys” key or a “display generic keys” key.

A determination is made in step 641 regarding whether menu-specific keys are to be displayed. That is, it is determined if the user has specified that menu-specific keys are desired. If the determination is that menu-specific keys are to be displayed, process flow proceeds to step 645 in which the IVR system commands a command channel to cause the menu-specific keys to effectively be displayed on the dynamic keypad. The command channel may cause the menu-specific keys to effectively be displayed by causing different light emitters within the keys of the dynamic keypad to be lit to form desired images. Once the command channel causes menu-specific keys to be displayed, the IVR system obtains input via the dynamic keypad in step 649. Then, in step 653, the IVR system process the input, and the process of soliciting and obtaining input is completed.

Returning to step 641, if it is determined that menu-specific keys are not to be displayed, the indication is that the user did not request menu-specific keys. As such, process flow moves from step 641 to step 657 in which the IVR system commands the control channel to display generic, e.g., default, keys on the dynamic keypad. The generic keys may be generic to the application associated with the menu segment or, alternatively, the generic keys may be generic with respect to the menu segment. From step 657, process flow proceeds to step 649 in which the IVR system obtains input from the dynamic keypad.

Returning back to step 637, if it is determined that dynamic keys are not supported, the indication may be that either the networked phone and/or the application associated with the menu segment does not support dynamic keys. Accordingly, process flow moves from step 637 to step 649 in which the IVR system obtains input from the keypad.

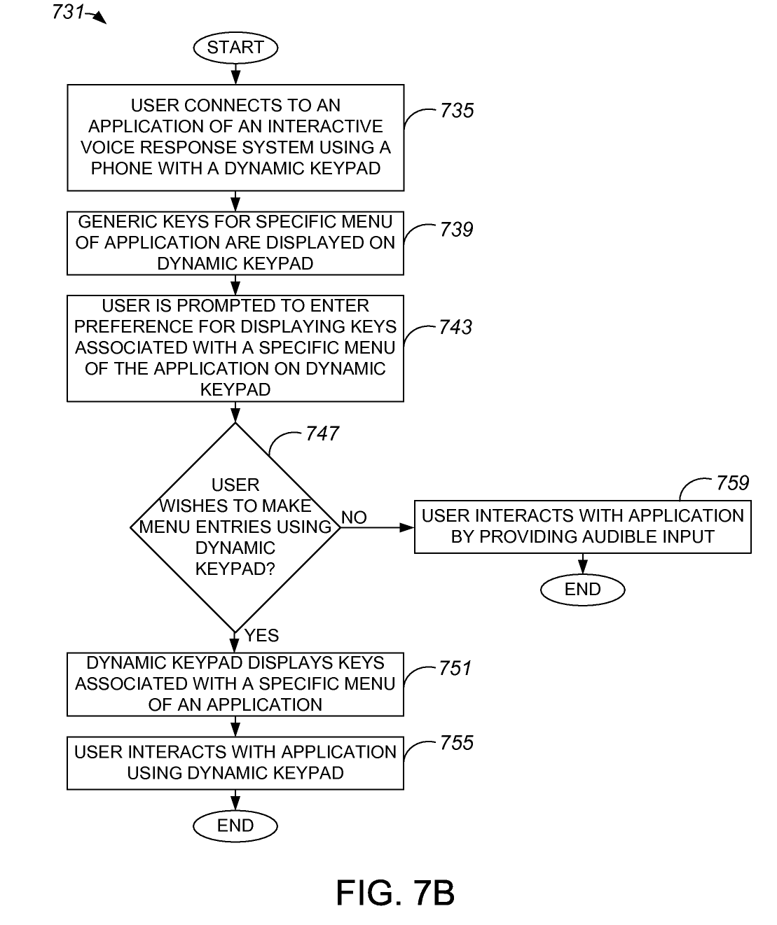

FIG. 7A is a process flow diagram which illustrates a method of a user utilizing dynamic keys of a networked phone that are substantially automatically provided in accordance with an embodiment of the present invention. A process 701 of utilizing dynamic keys begins at step 705 in which a user connects to an application of an IVR system using a networked phone with a dynamic keypad. After a connection is made between the networked phone and the application, i.e., after an active connection is made, keys associated with a specific menu of the application are displayed in the dynamic keypad in step 709.

Once keys are displayed to the user, a determination is made in step 713 regarding whether the user wishes to make menu entries, e.g., respond to queries, using the dynamic keypad. If it is determined that the user will make menu entries using the dynamic keypad, process flow moves from step 713 to step 717 in which the user interacts with the application via the dynamic keypad. After the user interacts with the application using the dynamic keypad, the process of utilizing dynamic keys is completed.

Alternatively, if it is determined in step 713 that the user does not wish to make menu entries using the dynamic keypad, the indication is that the user will verbally respond to queries. As such, in step 721, the user interacts with the application by providing audible input to the application. The process of utilizing dynamic keys is completed once the user provides audible input.

In one embodiment, a user may be allowed to determine whether menu-specific keys are to be displayed on a dynamic keypad of a networked phone, or whether “generic” keys are to be displayed. Referring next to FIG. 7B, a method for allowing a user to request the use of menu-specific keys will be described in accordance with an embodiment of the present invention. A process 731 of obtaining and utilizing menu-specific keys begins at step 735 in which a user connects to an application of an IVR system using a networked phone which includes a dynamic keypad. “Generic” keys for a specific menu of the application are displayed on the dynamic keypad in step 739. That is, default keys for the specific menu are displayed. It should be appreciated that the “generic” or default keys are typically generic with respect to the overall application, and may either be preselected by the user or by the overall application. “Generic” keys may be associated with a dynamic keypad that has a numeric display, e.g., dynamic keypad 108 of FIG. 1B.

After “generic” keys are displayed, the IVR system prompts the user in step 743 to enter a preference regarding the dynamic keys displayed in the dynamic keypad. In one embodiment, the user may be prompted to select a menu-specific dynamic keypad. A voice or a recording associated with the application may illicit a selection of and an implementation of an appropriate dynamic keypad, if a dynamic keypad is supported. The application is generally arranged to support both a dynamic keypad and a standard keypad, as the flows, e.g., key sequences to provide particular inputs, associated with using a dynamic keypad are substantially the same as the flows associated with using a standard keypad.

It is determined in step 747 whether the user has a preference for a menu-specific dynamic keypad. If the user effectively requests a menu-specific dynamic keypad, process flow moves to step 751 in which menu-specific keys are displayed in the dynamic keypad. Then, the user interacts with the application using the dynamic keypad in step 755, and the process of obtaining and utilizing menu-specific keys is completed.

Alternatively, if it is determined in step 747 that the user does not wish to make menu entries using a dynamic keypad, the implication is that the user wishes to interact with the application by providing audible input, e.g., spoken input. The process of obtaining and utilizing menu-specific keys is completed once the user interacts with the application by providing audio input.

Although only a few embodiments of the present invention have been described, it should be understood that the present invention may be embodied in many other specific forms without departing from the spirit or the scope of the present invention. By way of example, while light emitters such as organic LEDs have been described as being suitable for configuring menu-specific keys, keys may be configured in a variety of different ways. In other words, dynamic keys are not limited to having images created thereon by light emitters such as LEDs. Images may also be created using LCDs, electronic ink technology, and other suitable display technologies. For a softphone, images may be displayed on a variety of different screens including, but not limited to, computer screens, televisions, and webpads.

A dynamic keypad has been described as being suitable for use in displaying keys associated with applications such as a voice mailbox application and a pay-per-view application. It should be appreciated that keys associated with a variety of different applications may be displayed on a dynamic keypad. For instance, keys associated with a bank transactions application, such as “transfer money” and “check account balances” keys may be displayed on a dynamic keypad.

While a dynamic keypad may be used in IVR applications that provide audible explanations of menu options, a dynamic keypad may also be used with applications that do not include audible explanations. For example, a voice mail application may be arranged such that a user may use a dynamic keypad without being provided with audible explanations. In such a voice mail application, an audible cue to “select an option to play back messages” may not necessarily include audible explanations of options such as “press five to play,” as a user may see a “play” key displayed on his or her dynamic keypad.

Additionally, audible cues may also be substantially eliminated from an application. For instance, in a voice mail application, a user may be expected to understand that when “play” and “stop” keys are displayed on a dynamic keypad, he or she is to listen to messages. Hence, an audible cue from the voice mail application that prompts the user to select an option to listen to his or her messages may not necessarily be provided.

In one embodiment, a dynamic keypad may be used to bridge a networked phone to systems or interfaces used by persons with hearing impairments. Appropriate images may be displayed on the dynamic keypad to facilitate the ability for such persons to access appropriate interfaces that provide services for persons with hearing impairments.

A dynamic keypad may facilitate translations of audible cues and explanations into different languages. By way of example, audible cues provided by menus of an IVR application in one language may be associated with dynamic keys that are displayed with images and/or text that is in a second language. Hence, a user who understands the second language but not the first language may effectively interact with the menus of the IVR application. It should be appreciated that language translation functionality may be included in any or all of an IVR system, a transformer with control channel logic, or a networked phone.

A networked phone with a dynamic keypad on which images may be displayed on keys may be used to facilitate communication between a user of the networked phone and an IVR application in an environment with relatively loud ambient noise. In such an environment, if a user is unable to hear audible commands or options, the user may view the images displayed on the keys of his or her dynamic keyboard to ascertain what audible commands are likely being provided.

A dynamic keypad has generally been described as displaying images on keys that are effectively pictures. In one embodiment, a dynamic keypad may be arranged to display videos on keys without departing from the spirit or the scope of the present invention. For example, a video clip may be displayed on a key as a preview.

In addition to displaying core data, or data associated with an IVR application, on dynamic keys, other information may generally be displayed on dynamic keys. Such information may include, but is not limited to, advertisements such as advertisements for a company associated with the IVR application.

While the present invention has generally been described as being suitable for use with an IVR application or server, the present invention may be used with respect to other applications or servers. For instance, a dynamic keypad may be suitable for use with a system that includes a video on demand application or server.

The steps associated with the methods of the present invention may vary widely. Steps may be added, removed, altered, combined, and reordered without departing from the spirit of the scope of the present invention. By way of example, while processes of soliciting and obtaining input using an IVR system include obtaining input via a dynamic keypad, the input may instead be obtained in an aural manner using voice recognition, or using a combination of voice recognition and keypad entries. Therefore, the present examples are to be considered as illustrative and not restrictive, and the invention is not to be limited to the details given herein, but may be modified within the scope of the appended claims.

What is claimed is:

1. A networked phone apparatus comprising:
a dynamic keypad, the dynamic keypad including a plurality of dynamic keys, the plurality of dynamic keys being arranged to display images, wherein the dynamic keypad is arranged to be used as a phone keypad; and
control channel logic, the control channel logic being arranged to cause the images displayed on the plurality of dynamic keys to be changed.

2. The networked phone apparatus of claim 1 wherein the control channel logic is further arranged to cause the images displayed on the plurality of dynamic keys to be changed based on a command received from an interactive voice response (IVR) system.

3. The networked phone apparatus of claim 1 wherein the control channel logic is arranged to cause a first set of the images to be displayed on the plurality of dynamic keys when a first menu associated with the IVR system is active and to cause a second set of images to be displayed on the plurality of dynamic keys when a second menu associated with the IVR system is active.

4. The networked phone apparatus of claim 2 wherein the control channel logic is further arranged to cause images associated with a default keypad configuration to be displayed on the plurality of dynamic keys when the networked phone apparatus does not have an active connection to the IVR system.

5. The networked phone apparatus of claim 2 wherein the dynamic keypad is arranged to obtain an input, and the control channel logic is further arranged to cause the input to be provided to the IVR system.

6. The networked phone apparatus of claim 1 wherein the dynamic keypad is arranged to obtain an input, the networked phone apparatus further including:
dialing logic, the dialing logic being arranged to cause the input to be translated into a phone number, the dialing logic further being arranged to cause the phone number to be dialed.

7. The networked phone apparatus of claim 1 wherein the plurality of dynamic keys includes a plurality of light emitting diodes (LEDs), the plurality of LEDs being arranged to cause the images to be displayed, and wherein the control channel logic is arranged to control the images by controlling the plurality of light emitting diodes.

8. A method comprising:
displaying a first image on a first dynamic key of a plurality of dynamic keys associated with a dynamic keypad of a networked phone;
receiving an input, the input being a selection of the first image; and
performing an action in response to the input.

9. The method of claim 8 further including:
establishing a connection between the networked phone and an interactive voice response (IVR) system, the IVR system including an application, wherein the first image is associated with the application.

10. The method of claim 9 wherein the first image is associated with an option of a first menu associated with the application, and wherein performing the action in response to the input includes activating the option.

11. The method of claim 9 wherein the first image is associated with a first menu of the application, the method further including:
determining if a second menu associated with the application is initiated; and
displaying a second image on the first dynamic key instead of the first image it if is determined that the second menu is initiated.

12. The method of claim 9 wherein the first image is associated with a first menu of the application, the method further including:
requesting that the first image be displayed on the first dynamic key.

13. The method of claim 8 wherein the first image is associated with a phone number, and performing the action in response to the input includes dialing the phone number.

14. The method of claim 8 wherein the plurality of dynamic keys includes a plurality of light emitters, and displaying the first image on the first dynamic key includes controlling the plurality of light emitters.

15. Logic encoded in one or more tangible media for execution and when executed operable to:
cause a first image to be displayed on a first dynamic key of a plurality of dynamic keys associated with a dynamic keypad of a networked phone;
cause an input to be received, the input being a selection of the first image; and
cause an action to be performed in response to the input.

16. The logic of claim 15 further operable to:
cause a connection to be established between the networked phone and an interactive voice response (IVR) system, the IVR system including an application, wherein the first image is associated with the application.

17. The logic of claim 16 wherein the first image is associated with an option of a first menu associated with the application, and wherein the logic operable to cause the action to be performed in response to the input is operable to cause the option to be activated.

18. The logic of claim 16 wherein the first image is associated with a first menu of the application, the logic further being operable to:
cause a determination of whether a second menu associated with the application is initiated; and
cause a second image to be displayed on the first dynamic key instead of the first image it if the determination is that that the second menu is initiated.

19. The logic of claim 16 wherein the first image is associated with a first menu of the application, the logic further being operable to:
cause a request to be made to display the first image on the first dynamic key.

20. The logic of claim 15 wherein the first image is associated with a phone number, and the logic operable to cause the action to be performed in response to the input includes logic operable to cause the phone number to be dialed.

21. An apparatus comprising:
means for displaying a first image on a first dynamic key of a plurality of dynamic keys associated with a dynamic keypad of a networked phone;
means for receiving an input, the input being a selection of the first image; and
means for performing an action in response to the input.
